(19) United States
(12) Patent Application Publication
(10) Pub. No.: US 2025/0203235 A1
(43) Pub. Date: Jun. 19, 2025

(54) IMAGE SENSING DEVICE

(71) Applicant: SK hynix Inc., Icheon-si (KR)

(72) Inventors: Sang Jin PARK, Icheon-si (KR); Seung Min HAN, Icheon-si (KR)

(21) Appl. No.: 18/933,933

(22) Filed: Oct. 31, 2024

(30) Foreign Application Priority Data
Dec. 18, 2023 (KR) 10-2023-0184458

(51) Int. Cl. H04N 25/677; H01L 27/146; H04N 25/69

(52) U.S. Cl. CPC H04N 25/677; H04N 25/69; H10F 39/8037; H10F 39/811

(57) ABSTRACT

An image sensing device includes first conductive lines; second conductive lines disposed adjacent to the first conductive lines; a top test pad circuit including a first top test pad and a second top test pad; a bottom test pad circuit including a first bottom test pad and a second bottom test pad; a top switching circuit configured to connect a first terminal of each of the first conductive lines to the first top test pad and connect a first terminal of each of the second conductive lines to the second top test pad, based on a first switching signal; and a bottom switching circuit configured to connect a second terminal of each of the first conductive lines to the first bottom test pad and connect a second terminal of each of the second conductive lines to the second bottom test pad, based on a second switching signal.

### CROSS-REFERENCE TO RELATED APPLICATION

This patent document claims the priority and benefits of Korean patent application No. 10-2023-0184458, filed on Dec. 18, 2023, which is incorporated by reference in its entirety as part of the disclosure of this patent document.

### TECHNICAL FIELD

The technology and implementations disclosed in this patent document generally relate to an image sensing device.

### BACKGROUND

Image sensing devices are devices that convert optical images into electrical signals. With the recent development of automotive, medical, computer and communication industries, the demand for highly integrated, higher-performance image sensing devices is rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to an image sensing device that can allow for locating a signal transmission line where a column fixed pattern noise (CFPN) occurs and a location of the signal transmission line where a short circuit occurs. In an embodiment of the disclosed technology, an image sensing device may include a plurality of first conductive lines extending in a first direction; a plurality of second conductive lines extending in the first direction, each of the plurality of second conductive lines being disposed adjacent to each of the first conductive lines; a top test pad circuit including a first top test pad and a second top test pad; a bottom test pad circuit including a first bottom test pad and a second bottom test pad; a top switching circuit configured to connect a first terminal of each of the plurality of first conductive lines to the first top test pad and connect a first terminal of each of the plurality of second conductive lines to the second top test pad, based on a first switching signal; and a bottom switching circuit configured to connect a second terminal of each of the plurality of first conductive lines to the first bottom test pad and connect a second terminal of each of the second conductive lines to the second bottom test pad, based on a second switching signal.

In another embodiment of the disclosed technology, an image sensing device may include a plurality of first conductive lines configured to extend parallel to each other in a first direction; a plurality of second conductive lines located adjacent to the first conductive lines and configured to extend parallel to each other in the first direction; a top test pad circuit configured to include a first top test pad and a second top test pad; a bottom test pad circuit configured to include a first bottom test pad and a second bottom test pad; a plurality of first top switching elements, first source or drain terminals of the plurality of first top switching elements being connected in a one-to-one correspondence with first terminals of the first conductive lines, second source or drain terminals of the plurality of first top switching elements being commonly connected to the first top test pad; a plurality of second top switching elements, first source or drain terminals of the plurality of second top switching elements being connected in a one-to-one correspondence with first terminals of the second conductive lines, second source or drain terminals of the plurality of second top switching elements being commonly connected to the second top test pad; a plurality of first bottom switching elements, first source or drain terminals of the plurality of first bottom switching elements being connected in a one-to-one correspondence with second terminals of the first conductive lines, second source or drain terminals of the plurality of first bottom switching elements being commonly connected to the first bottom test pad; and a plurality of second bottom switching elements, first source or drain terminals of the plurality of second bottom switching elements being connected in a one-to-one correspondence with second terminals of the second conductive lines, second source or drain terminals of the plurality of second bottom switching elements being commonly connected to the second bottom test pad.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a plan view illustrating a structure of pixel array in an image sensing device based on some implementations of the disclosed technology.

FIG. 2 is a cross-sectional view illustrating an example structure of pixel array along the line X-X′ shown in FIG. 1 based on some implementations of the disclosed technology.

FIG. 3 is a circuit diagram illustrating an example structure of a unit pixel (PX) formed in the pixel array shown in FIG. 1 based on some implementations of the disclosed technology.

FIG. 4 is a schematic diagram illustrating an example structure of an image sensing device based on an embodiment of the disclosed technology.

FIG. 5 is a schematic diagram illustrating an example structure of a portion of a top switching circuit shown in FIG. 4 based on some implementations of the disclosed technology.

FIG. 6 is a schematic diagram illustrating an example of a portion of a bottom switching circuit shown in FIG. 4 based on some implementations of the disclosed technology.

FIG. 7 is a diagram illustrating how to locate a short-circuited conductive line among all conductive lines and the location where a short circuit occurs in the short-circuited conductive line when a column fixed pattern noise (CFPN) occurs due to a short circuit between first and second conductive lines adjacent to each other.

FIG. 8 is a schematic diagram illustrating an example structure of an image sensing device based on another embodiment of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. The disclosed technology can be implemented in some embodiments to easily locate a “noisy” signal transmission line in an image sensing device where a column fixed pattern noise (CFPN) occurs and a location where a short circuit occurs in the noisy signal transmission line.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

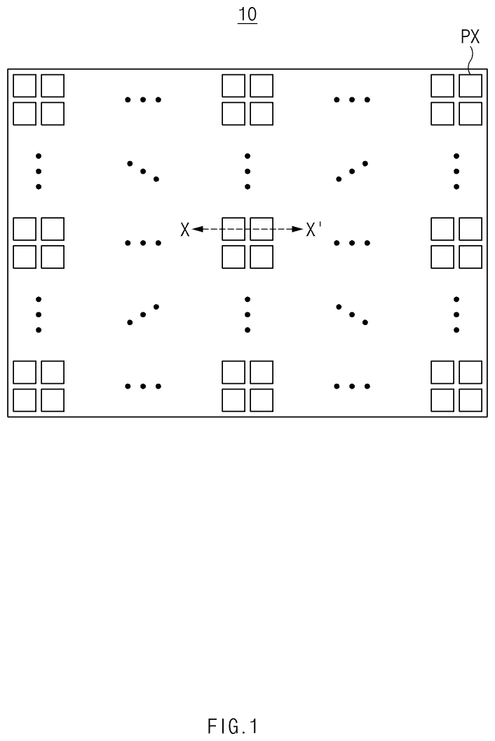

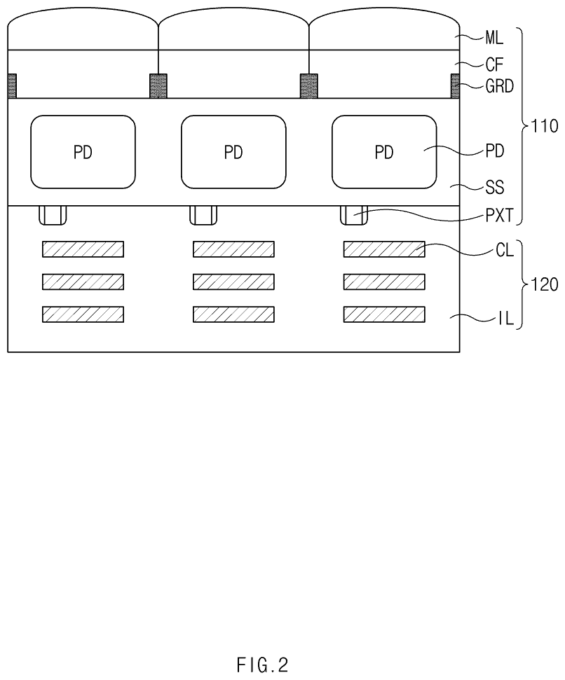

FIG. 1 is a plan view illustrating a structure of pixel array in an image sensing device based on some implementations of the disclosed technology. FIG. 2 is a cross-sectional view illustrating an example structure of pixel array along the line X-X′ shown in FIG. 1 based on some implementations of the disclosed technology.

Referring to FIGS. 1 and 2, the image sensing device may include a substrate layer 110 and an interconnect layer 120.

The substrate layer 110 may include the pixel array 10. the pixel array 10 may include a plurality of unit pixels (or image sensing pixel) (PXs) arranged in rows and columns. Each of the unit pixels (PXs) may include a photoelectric conversion element PD, color filters CF, microlenses ML and pixel transistors PXT.

The photoelectric conversion element PD may be formed in a substrate SS, and may generate and accumulate photocharges corresponding to incident light. For example, the photoelectric conversion element PD may include a photodiode, a phototransistor, a photogate, a pinned photodiode (PPD), or a combination thereof, but is not limited thereto.

The color filters CF and the microlenses ML may be formed over a back surface of the substrate SS. The pixel transistors PXT may be formed on a front surface opposite to the back surface of the substrate SS. A grid structure GRD may be formed between the color filters CF, and may prevent crosstalk between adjacent color filters.

The interconnect layer 120 may be formed under the front surface of the substrate SS. The interconnect layer 120 may include an interlayer insulation layer IL and conductive lines CL formed in the interlayer insulation layer IL. The conductive lines CL may be electrically connected to the pixel transistors PXT.

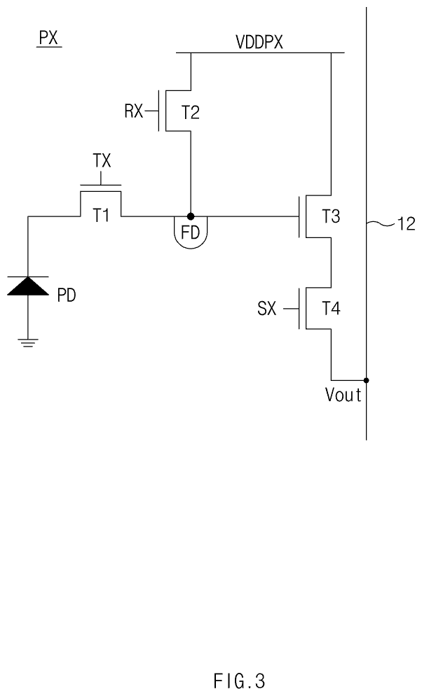

FIG. 3 is a circuit diagram illustrating an example structure of a unit pixel (PX) formed in the pixel array shown in FIG. 1 based on some implementations of the disclosed technology.

Referring to FIGS. 3, each of the unit pixels (PXs) may include a photoelectric conversion element PD, a floating diffusion node FD, a transfer transistor T1, a reset transistor T2, a source follower transistor T3 and a selection transistor T4.

The transfer transistor T1 may transmit photocharges accumulated in the photoelectric conversion element PD to the floating diffusion node FD based on the transfer signal TX. For example, the transfer transistor T1 may include an NMOS transistor that is connected to the floating diffusion node FD and photoelectric conversion element PD and receives a transfer signal TX through a gate terminal thereof.

The floating diffusion node FD may receive and accumulate photocharges generated by the photoelectric conversion element PD. The source follower transistor T3 may be controlled based on the amount of photocharges accumulated in the floating diffusion node FD.

The reset transistor T2 may periodically reset the floating diffusion node FD. When the reset signal RX is enabled and the reset transistor T2 is turned on, a first pixel power-supply voltage (VDDPX) is transferred to the floating diffusion node FD. Accordingly, photocharges accumulated in the floating diffusion node FD may be discharged such that the floating diffusion node FD can be reset. For example, the reset transistor T2 may include an NMOS transistor that is connected to the floating diffusion node FD and a pixel power-supply voltage (VDDPX) node and receives the reset signal RX through a gate terminal thereof.

The source follower transistor T3 may be or include a source follower buffer amplifier that generates a source-drain current in proportion to the amount of charges of the floating diffusion node FD. The source follower transistor T3 may amplify a change in potential at the floating diffusion node FD, and the amplified signal may be output to the selection transistor T4 as a pixel signal (Vout). For example, the source follower transistor T3 may include an NMOS transistor that is connected to the floating diffusion node (FD) through a gate terminal thereof and is connected to the pixel power-supply voltage (VDDPX) node and the selection transistor T4.

The selection transistor T4 may receive the pixel signal (Vout) from the source follower transistor T3 and output the pixel signal (Vout) to the output line (or column line) 12 based on the row selection signal SX. For example, the selection transistor T4 may include an NMOS transistor that is connected to the source follower transistor T3 and the output line 12 and receives the row selection signal SX through a gate terminal thereof.

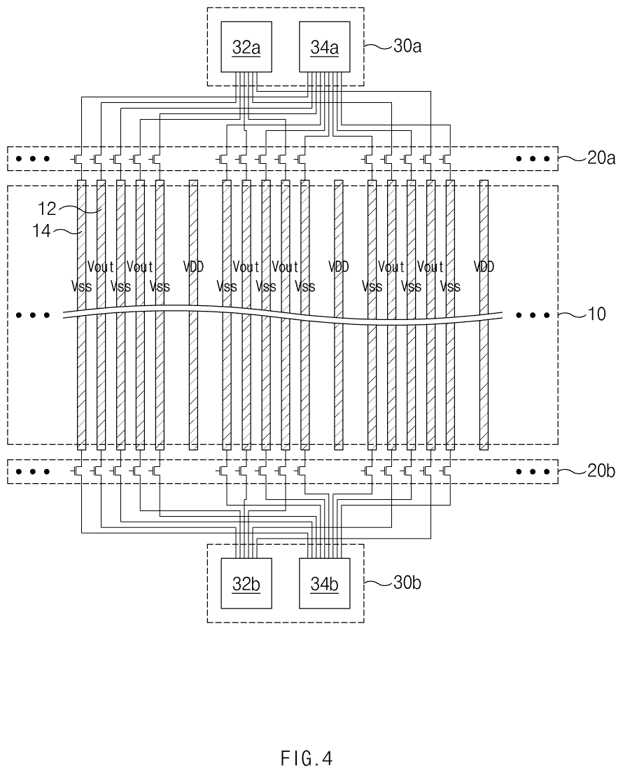

FIG. 4 is a schematic diagram illustrating an example structure of an image sensing device based on an embodiment of the disclosed technology.

Referring to FIG. 4, the image sensing device may include a plurality of first conductive lines 12, a plurality of second conductive lines 14, a top switching circuit 20a, a bottom switching circuit 20b, a top test pad circuit 30a, and a bottom test pad circuit 30b.

The first conductive lines 12 may be disposed to vertically overlap a pixel array 10 that includes a plurality of unit pixels (PXs) arranged in the pixel array 10, and may include a plurality of conductive lines arranged in a first direction (e.g., a column direction). For example, in the case of a backside illumination (BSI) type image sensing device as shown in FIG. 2, the first conductive lines 12 may include metal lines that extend parallel to each other along a column direction of the pixel array 10 within the interconnect layer 120 disposed under the front surface of the substrate layer 110 in which the pixel array 10 is formed. The pixel array 10 includes an array of image sensing pixels arranged in rows and columns and each image sensing pixel includes an optical detector that converts light into a pixel signal so that the pixel array 10 can capture the image information carried by incident light that is received and detected by the image sensing pixels.

The first conductive lines 12 may include pixel signal output lines as shown in FIG. 3 that transmit pixel signals (Vout) generated by photoelectric conversion of incident light in unit pixels. For example, the first conductive lines 12 may include conductive lines that are commonly connected to selection transistors T4 of the unit pixels (PXs) located at the same column line within the pixel array 10 to transmit pixel signals (Vout) generated by the unit pixels (PXs) of the corresponding column line. In the embodiments of the disclosed technology, a case in which the first conductive line 12 is a pixel signal output line will be exemplarily described.

The second conductive lines 14 may be disposed to overlap the pixel array 10 in a vertical direction, and may include a plurality of conductive lines that is arranged adjacent to the first conductive lines 12 in the first direction. For example, the second conductive lines 14 may be respectively located adjacent to the first conductive lines 12 in the same layer or at the same level as the first conductive lines 12. The second conductive lines 14 may include metal lines (power transmission lines) that supply a ground voltage (Vss).

Referring to FIG. 4, in the image sensing device based on an embodiment, two first conductive lines 12 and three second conductive lines 14 may be alternately arranged to form one conductive line group, and conductive lines for transmitting a power voltage (VDD) may be arranged between corresponding conductive line groups, but the disclosed technology is not limited thereto.

The top switching circuit 20a may selectively connect the first conductive lines 12 and the second conductive lines 14 to the top test pad circuit 30a according to switching signals. For example, upon receiving the switching signals, the top switching circuit 20a may selectively connect one of the first conductive lines 12 to the first top test pad 32a, and may selectively connect one of the second conductive lines 14 to the second top test pad 34a. In some implementations, the first conductive lines connected to the first top test pad 32a and the second conductive lines connected to the second top test pad 34a may be conductive lines located adjacent to each other.

The top switching circuit 20a may include top switching elements (e.g., transistors) that are disposed between the top test pad circuit 30a and one end of the corresponding conductive line such that the top switching elements can be arranged in a one-to-one correspondence with the first conductive lines 12 and the second conductive lines 14. Each top switching element may be electrically connected to one end of the conductive line corresponding thereto. Additionally, each top switching element may be electrically connected to the first top test pad 32a or the second top test pad 34a. For example, all of the top switching elements connected to the first conductive lines 12 may be connected to the first top test pad 32a, and all of the top switching elements connected to the second conductive lines 14 may be connected to the second top test pad 34a.

The bottom switching circuit 20b may selectively connect the first conductive lines 12 and the second conductive lines 14 to the bottom test pad circuit 30b according to switching signals. For example, upon receiving the switching signals, the bottom switching circuit 20b may selectively connect one of the first conductive lines 12 to the first bottom test pad 32b, and may selectively connect one of the second conductive lines 14 to the second conductive lines 14. In this case, the first conductive lines connected to the first bottom test pad 32b and the second conductive lines connected to the second bottom test pad 34b may refer to conductive lines located adjacent to each other.

The first conductive lines and the second conductive lines connected to the bottom test pad circuit 30b by the bottom switching circuit 20b may be the same conductive lines as the first conductive lines and the second conductive lines connected to the top test pad circuit 30a by the top switching circuit 20a. For example, one of the first conductive lines 12 may be electrically connected to the first top test pad 32a by the top switching circuit 20a, and may also be electrically connected to the first bottom test pad 32b by the bottom switching circuit 20b. Likewise, one of the second conductive lines 14 may be electrically connected to the second top test pad 34a by the top switching circuit 20a, and may be electrically connected to the second bottom test pad 34b by the bottom switching circuit 20b.

The bottom switching circuit 20b may include bottom switching elements (e.g., transistors) disposed between the bottom test pad circuit 30b and the other end of the corresponding conductive line so that the bottom switching elements are arranged in a one-to-one correspondence with the first conductive lines 12 and the second conductive lines 14. Each bottom switching element may be electrically connected to the other end of the corresponding conductive line. Additionally, each bottom switching element may be electrically connected to the first bottom test pad 32b or the second bottom test pad 34b. For example, all bottom switching elements connected to the first conductive lines 12 may be connected to the first bottom test pad 32b, and all bottom switching elements connected to the second conductive lines 14 may be connected to the second bottom test pad 34b.

The top test pad circuit 30a may include a first top test pad 32a connected to the first conductive lines 12 by the top switching circuit 20a and a second top test pad 34a connected to the second conductive lines by the top switching circuit 20a. In a test mode, a high level voltage may be applied to the first top test pad 32a, and a low level voltage may be applied to the second top test pad 34a.

The bottom test pad circuit 30b may include a first bottom test pad 32b connected to the first conductive lines 12 by the bottom switching circuit 20b and the second bottom test pad 34b connected to the second conductive lines by the bottom switching circuit 20b. In the test mode, a high level voltage may be applied to the first bottom test pad 32b, and a low level voltage may be applied to the second bottom test pad 34b. In some implementations, the same voltage may be applied to the first top test pad 32a and the first bottom test pad 32b, and the same voltage may be applied to the second top test pad 34a and the second bottom test pad 34b.

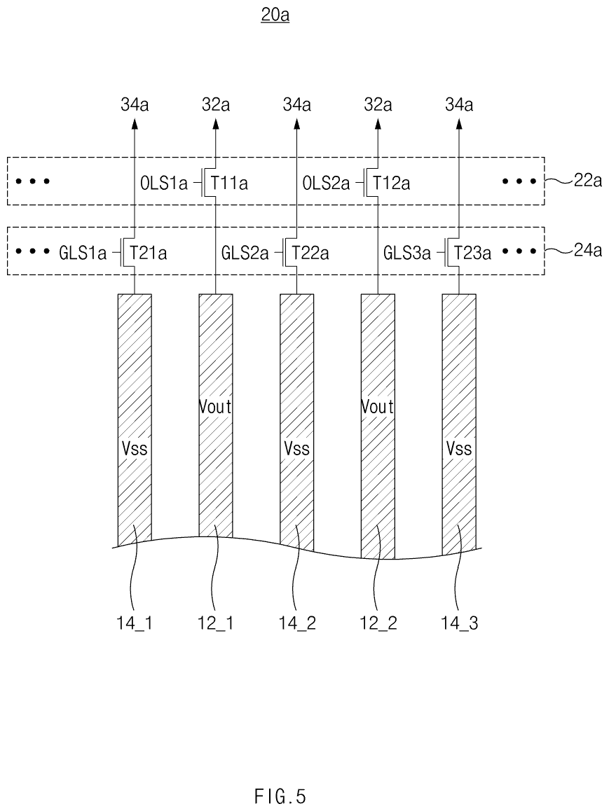

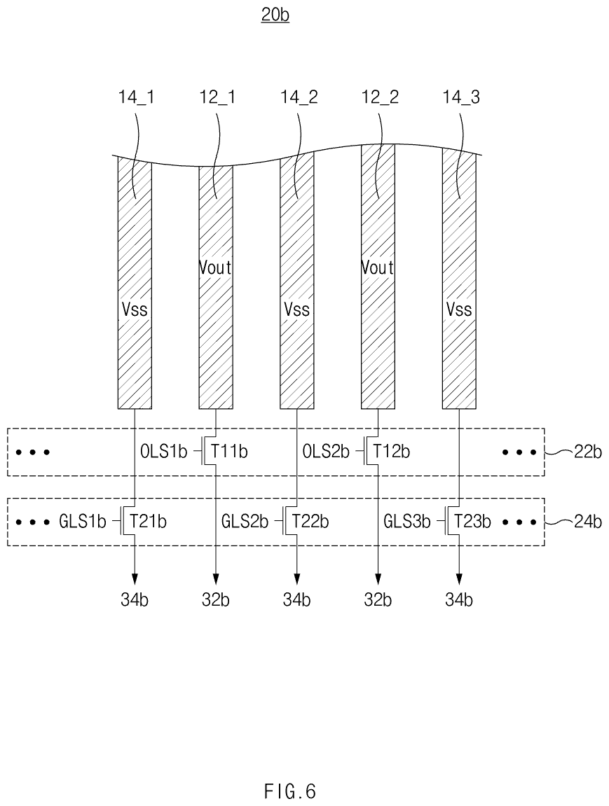

FIG. 5 is a schematic diagram illustrating an example of a detailed structure of a portion of the top switching circuit shown in FIG. 4 based on some implementations of the disclosed technology. FIG. 6 is a schematic diagram illustrating an example of a portion of the bottom switching circuit shown in FIG. 4 based on some implementations of the disclosed technology.

Referring to FIG. 5, the top switching circuit 20a may include a first top switching circuit 22a and a second top switching circuit 24a.

The first top switching circuit 22a may include a plurality of first top switching elements (T11a, T12a), one terminal (e.g., “first source or drain terminal”) of which is connected to the first top test pad 32a and another terminal (e.g., “second source or drain terminal”) of which is connected to the corresponding first conductive lines (12_1, 12_2). The first top switching elements (T11a, T12a) may respectively receive output line switching signals (OLS1a, OLS2a) through gate terminals thereof, and may be respectively turned on or off based on the output line switching signals (OLS1a, OLS2a). For example, one of the first top switching elements (T11a, T12a) may be selectively turned on by the output line switching signals (GLS1a, GLS2a), and the others excluding the turned-on first top switching element may be turned off. The first top switching elements (T11a, T12a) may be sequentially turned on one by one. The first top switching elements (T11a, T12a) may include MOS transistors.

The second top switching circuit 24a may include a plurality of second top switching elements (T21a, T22a, T23a). In one example, one terminal of each of the plurality of second top switching elements (T21a, T22a, T23a) is connected to the second top test pad 34a and another terminal of each of the plurality of second top switching elements (T21a, T22a, T23a) is respectively connected to the corresponding second conductive lines (14_1, 14_2, 14_3). The second top switching elements (T21a, T22a, T23a) may respectively receive ground line switching signals (GLS1a, GLS2a, GLS3a) through gate terminals thereof, and may be respectively turned on or off based on the ground line switching signals (GLS1a, GLS2a, GLS3a). For example, one of the second top switching elements (T21a, T22a, T23a) may be selectively turned on by the ground line switching signals (GLS1a, GLS2a, GLS3a), and the others excluding the turned-on second top switching element may be turned off. The second top switching elements (T21a, T22a, T23a) may be sequentially turned on one by one. The second top switching elements (T21a, T22a, T23a) may include MOS transistors.

Referring to FIG. 6, the bottom switching circuit 20b may include a first bottom switching circuit 22b and a second bottom switching circuit 24b.

The first bottom switching circuit 22b may include a plurality of first bottom switching elements (T11b, T12b). In one example, one terminal of each of the plurality of first bottom switching elements (T11b, T12b) is connected to the first bottom test pad 32b and another terminal of each of the plurality of first bottom switching elements (T11b, T12b) is connected to its corresponding first conductive line (12_1 or 12_2). The first bottom switching elements (T11b, T12b) may respectively receive output line switching signals (OLS1b, OLS2b) through gate terminals thereof, and may be respectively turned on or off based on the output line switching signals (OLS1b, OLS2b). For example, one of the first bottom switching elements (T11b, T12b) may be selectively turned on by the output line switching signals (GLS1b, GLS2b), and the others excluding the turned-on first bottom switching element may be turned off. The first bottom switching elements (T11b, T12b) may be turned on one by one sequentially in the same order as the first top switching elements (T11a, T12a). The first bottom switching elements (T11b, T12b) may include MOS transistors.

The second bottom switching circuit 24b may include a plurality of second bottom switching elements (T21b, T22b, T23b). In one example, one terminal of each of the plurality of second bottom switching elements (T21b, T22b, T23b) is connected to the second bottom test pad 34b and another terminal of each of the plurality of second bottom switching elements (T21b, T22b, T23b) is connected to its corresponding second conductive line (14_1, 14_2, or 14_3). The second bottom switching elements (T21b, T22b, T23b) may respectively receive ground line switching signals (GLS1b, GLS2b, GLS3b) through gate terminals thereof, and may be respectively turned on or off based on the ground line switching signals (GLS1b, GLS2b, GLS3b). For example, one of the second bottom switching elements (T21b, T22b, T23b) may be selectively turned on by the ground line switching signals (GLS1b, GLS2b, GLS3b), and the others excluding the turned-on second bottom switching element may be turned off. The second bottom switching elements (T21b, T22b, T23b) may be turned on one by one sequentially in the same order as the second top switching elements (T21a, T22a, T23a). The second bottom switching elements (T21b, T22b, T23b) may include MOS transistors.

The first top switching circuit 22a and the first bottom switching circuit 22b may connect one of the first conductive lines (12_1, 12_2) to the first top test pad 32a and the first bottom test pad 32b based on the output line switching signals (OLS1a, OLS2a, OLS1b, OLS2b). For example, the output line switching signals (OLS1a, OLS1b) may be activated simultaneously and the first top switching element T11a and the first bottom switching element T11b may be turned on simultaneously, so that the first conductive line 12_1 may be connected to the first top test pad 32a and the first bottom test pad 32b.

In addition, the second top switching circuit 24a and the second bottom switching circuit 24b may connect one of the second conductive lines (14_1, 14_2, 14_3) to both the second top test pad 34a and the second bottom test pad 34b based on the ground line switching signals (GLS1a, GLS2a, GLS3a, GLS1b, GLS2b, GLS3b). For example, the ground line switching signals (GLS1a, GLS1b) may be activated simultaneously and the second top switching element T21a and the second bottom switching element T21b may be turned on simultaneously, so that the second conductive line 14_1 adjacent to the first conductive line 12_1 may be connected to the second top test pad 34a and the second bottom test pad 34b.

The switching elements (T11a, T12a, T11b, T12b, T21a, T22a, T23a, T21b, T22b, T23b) of the top switching circuit 20a and the bottom switching circuit 20b are all formed with the same size (e.g., the same channel resistance).

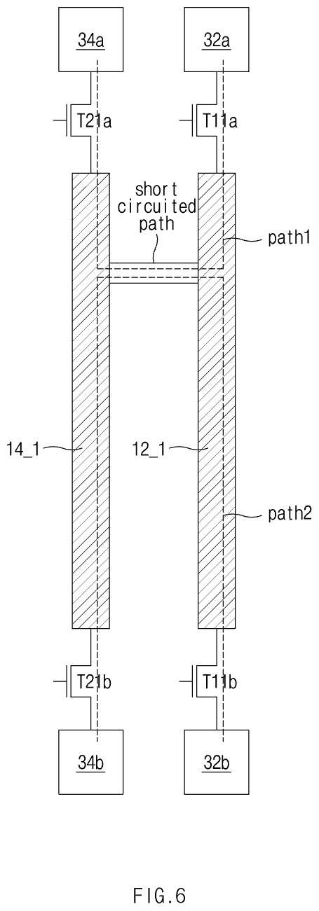

FIG. 7 is a diagram illustrating the principle of finding a short-circuited conductive line among all conductive lines and the location where short-circuit occurs in the short-circuited conductive line when CFPN (Column Fixed Pattern Noise) occurs due to a short circuit between first and second conductive lines adjacent to each other.

Referring to FIGS. 3 to 6, during the test mode, a test device (not shown) may apply a preset high-level voltage to the first top test pad 32a and the first bottom test pad 32b, and may apply a preset low-level voltage to the second top test pad 34a and the second bottom test pad 34b.

When a voltage is applied to the test pads (32a, 32b, 34a, 34b), the test device may sequentially connect the first conductive lines 12 to the first top test pad 32a and the first bottom test pad 32b, and sequentially connect the second conductive lines 14 to the second top test pad 34a and the second bottom test pad 34b. In some implementations, the first conductive line connected to the first top test pad 32a and the first bottom test pad 32b and the second conductive line connected to the second top test pad 34a and the second bottom test pad 34b may be adjacent to each other.

For example, the test device may connect only the second conductive line 14_1 and the first conductive line 12_1 to the corresponding top test pad and the corresponding bottom test pad by using the output line switching signals (OLS1a, OLS2a, OLS1b, OLS2b) and the ground line switching signals (GLS1a, GLS2a, GLS3a, GLS1b, GLS2b, GLS3b). Subsequently, the test device may connect only the first conductive line 12_1 and the second conductive line 14_2 to the corresponding top test pad and the corresponding bottom test pad. In some implementations, since the second conductive lines (14_1, 14_2) are located adjacent to both sides of the first conductive line 12_1, the test device may enable the first conductive line 12_1 to remain connected to the top test pad 32a and the bottom test pad 32b while the connection of the second conductive lines (14_1, 14_2) is being replaced.

Subsequently, the test device may connect only the second conductive line 14_2 and the first conductive line 12_2 to the corresponding top test pad and the corresponding bottom test pad. Likewise, since the first conductive lines (12_1, 12_2) are located adjacent to both sides of the second conductive line 14_2, the test device may enable the second conductive line 14_2 to remain connected to the top test pad 34a and the bottom test pad 34b while the connection of the first conductive lines (12_1, 12_2) is being replaced.

The test device may sequentially connect both of the first conductive lines 12 and the second conductive lines 14 to the corresponding top test pad and bottom test pad in the same manner as above.

In the above-described process, as shown in FIG. 7, if short circuit occurs in the first conductive line 12_1 and the second conductive line 14_1 adjacent to each other, a current path through the corresponding short circuited path may be formed between each of the first top test pad 32a and the first bottom test pad 32b, each of which receives a high-level voltage, and each of the second top test pad 34a and the second bottom test pad 34b, each of which receives a low-level voltage. For example, as shown in FIG. 7, a current path (path1) through a short-circuit path may be formed between the first top test pad 32a and the second top test pad 34a, and a current path (path2) may be formed between the first bottom test pad 32b and the second bottom test pad 34b.

The test device may determine whether the current path (path1) is formed between the top test pads 32a and 34a and the current path (path2) is formed between the bottom test pads 32b and 34b, and may determine whether short-circuit has occurred between the conductive lines while determining which conductive lines have been short-circuited. For example, when the current paths (path1, path2) are formed, the test device may determine that a short circuit has occurred between the first and second conductive lines connected to the test pads (32a, 34a, 32b, 34b).

In addition, the test device may determine a resistance value R1 for the current path (path1) by using a voltage difference between the first top test pad 32a and the second top test pad 34a and a current value flowing through the current path (path1), and may determine a resistance value R2 for the current path (path2) by using a voltage difference between the first bottom test pad 32b and the second bottom test pad 34b and a current value flowing through the current path (path2).

The test device may estimate the region where a short circuit has occurred within the corresponding conductive line based on the ratios {R1/(R1+R2), R2/(R1+R2)} of these resistance values (R1, R2). For example, when the first conductive lines 12 and the second conductive lines 14 have the same material and the same line width (e.g., critical dimension CD), the resistance values (R1, R2) may be proportional to the distances of the corresponding current paths (path1, path2). As a result, the test device may estimate which one of the regions has been short-circuited using the ratios {R1/(R1+R2), R2/(R1+R2)} of the resistance values (R1, R2).

In some implementations, output lines of the image sensing device may be located adjacent to ground lines. As shown in FIG. 7, when short-circuit occurs between the output lines and the ground lines, CFPN (Column Fixed Pattern Noise) may occur. The position of the output line where CFPN has occurred can also be confirmed through an emission image obtained through an emission test. However, since CFPN appears throughout the corresponding output line, it is difficult to locate the region where a short circuit has occurred in the output line. However, in an embodiment, it is possible to easily locate the position of the output line where CFPN has occurred, and the position where a short circuit has occurred in the corresponding output line.

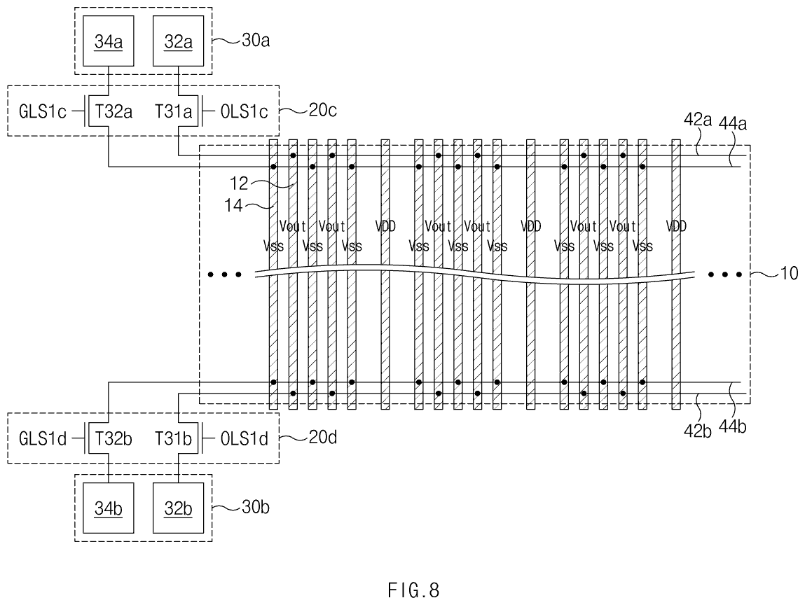

FIG. 8 is a schematic diagram illustrating an example structure of the image sensing device based on another embodiment of the disclosed technology.

In the embodiment of FIG. 8, the same reference numerals are used for the same components as those of FIG. 4, and as such redundant description thereof will herein be omitted. Hereinafter, the following embodiment of FIG. 7 will be described centering upon differences from the embodiment of FIG. 4 to avoid redundant description.

Referring to FIG. 8, the image sensing device may include a plurality of first conductive lines 12, a plurality of second conductive lines 14, a top switching circuit 20c, a bottom switching circuit 20d, a top test pad circuit 30a, and a bottom test pad circuit 30b.

In FIG. 8, one end of each of the first conductive lines 12 may be commonly connected by a first top common line 42a, and the other end of each of the first conductive lines 12 may be commonly connected by a first bottom common line 42b. Additionally, one end of each of the second conductive lines 14 may be commonly connected by a second top common line 44a, and the other end of each of the second conductive lines 14 may be commonly connected by a second bottom common line 44b.

A top switching circuit 20c may selectively connect the first top common line 42a and the second top common line 44a to the top test pad circuit 30a according to switching signals. The top switching circuit 20c may include top switching elements (T31a, T32a).

The top switching element T31a may connect the first top common line 42a to the first top test pad 32a of the top test pad circuit 30a according to the output line switching signal (OLS1c). The top switching element T32a may connect the second top common line 44a to the second top test pad 34a of the top test pad circuit 30a according to the ground line switching signal (GLS1c). The switching signals (OLS1c, GLS1c) may be activated only in the test mode.

A bottom switching circuit 20d may selectively connect the first bottom common line 42b and the second bottom common line 44b to the bottom test pad circuit 30b according to switching signals. The bottom switching circuit 20d may include bottom switching elements (T31b, T32b).

The bottom switching element T31b may connect the first bottom common line 42b to the first bottom test pad 32b of the bottom test pad circuit 30b according to the output line switching signal (OLS1d). The bottom switching element T32b may connect the second bottom common line 44b to the second bottom test pad 34b of the bottom test pad circuit 30b according to the ground line switching signal (GLS1d). The switching signals (OLS1d, GLS1d) may be activated only in the test mode. The switching signals (OLS1c, GLS1c, OLS1d, GLS1d) may be activated simultaneously in the test mode.

In an embodiment, when the conductive lines in which a short circuit has occurred between the conductive lines 12 and 14 have been confirmed through a separate test process, the image sensing device may be used to check where a short-circuit has occurred in the corresponding conductive lines. For example, conductive lines where short circuits have occurred may be confirmed through the emission image.

A test device (not shown) may apply a preset high-level voltage to the first top test pad 32a and the first bottom test pad 32b, and may apply a preset low-level voltage to the second top test pad 34a and the second bottom test pad 34b. In addition, the test device (not shown) may activate all of the switching signals (OLS1c, GLS1c, OLS1d, GLS1d) such that the common lines (42a, 42b, 44a, 44b) can be connected to the corresponding test pads (32a, 32b, 34a, 34b).

In some implementations, when short circuits occur in the first conductive line and the second conductive line adjacent to each other, a current path may be formed between the top test pads (32a, 34a) through the corresponding short-circuit path, and a current path may be formed between the bottom test pads (32b, 34b) through the corresponding short-circuit path.

The test device may determine a resistance value R1 using both a voltage difference between the first top test pad 32a and the second top test pad 34a and the current value of the corresponding current path, and may determine a resistance value R2 using both a voltage difference between the first bottom test pad 32b and the second bottom test pad 34b and the current value of the corresponding current path.

The test device may estimate the point where short-circuit has occurred within the previously recognized conductive lines based on the ratios {R1/(R1+R2), R2/(R1+R2)} of these resistance values (R1, R2).

As is apparent from the above description, the image sensing device based on some implementations of the disclosed technology may easily located a transmission line where a column fixed pattern noise (CFPN) occurs and a location where a short circuit has occurred in the transmission line.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of first conductive lines extending in a first direction;
a plurality of second conductive lines extending in the first direction, each of the plurality of second conductive lines being disposed adjacent to each of the first conductive lines;
a top test pad circuit including a first top test pad and a second top test pad;
a bottom test pad circuit including a first bottom test pad and a second bottom test pad;
a top switching circuit configured to connect a first terminal of each of the plurality of first conductive lines to the first top test pad and connect a first terminal of each of the plurality of second conductive lines to the second top test pad, based on a first switching signal; and
a bottom switching circuit configured to connect a second terminal of each of the plurality of first conductive lines to the first bottom test pad and connect a second terminal of each of the second conductive lines to the second bottom test pad, based on a second switching signal.

2. The image sensing device according to claim 1, wherein the top switching circuit is configured to:
based on the first switching signal, connect one of the plurality of first conductive lines to the first top test pad and connect one of the plurality of second conductive lines to the second top test pad.

3. The image sensing device according to claim 2, wherein the top switching circuit includes:
a plurality of first top switching elements, first terminals of the plurality of first top switching elements being connected in a one-to-one correspondence with the plurality of first conductive lines, second terminals of the plurality of first top switching elements being commonly connected to the first top test pad; and
a plurality of second top switching elements, first terminals of the plurality of second top switching elements being connected in a one-to-one correspondence with the plurality of second conductive lines, second terminals of the plurality of second top switching elements being commonly connected to the second top test pad.

4. The image sensing device according to claim 2, wherein the bottom switching circuit is configured to:
based on the second switching signal, connect one of the plurality of first conductive lines to the first bottom test pad and connect one of the plurality of second conductive lines to the second bottom test pad.

5. The image sensing device according to claim 4, wherein the bottom switching circuit is configured to:
based on the second switching signal, connect a first conductive line of the plurality of first conductive lines that is connected to the first top test pad to the first bottom test pad, and connect a second conductive line of the plurality of second conductive lines that is connected to the second top test pad to the second bottom test pad.

6. The image sensing device according to claim 4, wherein the bottom switching circuit includes:
a plurality of first bottom switching elements, first terminals of the plurality of first bottom switching elements being connected in a one-to-one correspondence with the plurality of first conductive lines, second terminals of the plurality of first bottom switching elements being commonly connected to the first bottom test pad; and
a plurality of second bottom switching elements, first terminals of the plurality of second bottom switching elements being connected in a one-to-one correspondence with the plurality of second conductive lines, second terminals of the plurality of second bottom switching elements being commonly connected to the second bottom test pad.

7. The image sensing device according to claim 1, wherein the top switching circuit is configured to:
based on the first switching signal, connect all of the plurality of first conductive lines to the first top test pad, and connect all of the plurality of second conductive lines to the second top test pad.

8. The image sensing device according to claim 7, further comprising:
a first top common line commonly connected to first terminals of all of the plurality of first conductive lines; and
a second top common line commonly connected to first terminals of all of the plurality of second conductive lines.

9. The image sensing device according to claim 8, wherein the top switching circuit includes:
a first top switching element, a first terminal of the first top switching element being connected to the first top common line, a second terminal of the first top switching element being connected to the first top test pad; and
a second top switching element, a first terminal of the second top switching element being connected to the second top common line, a second terminal of the second top switching element being connected to the second top test pad.

10. The image sensing device according to claim 7, wherein the bottom switching circuit is configured to:
based on the second switching signal, connect all of the plurality of second conductive lines to the first bottom test pad, and connect all of the plurality of second conductive lines to the second bottom test pad.

11. The image sensing device according to claim 10, further comprising:
a first bottom common line commonly connected to second terminals of all of the plurality of first conductive lines; and
a second bottom common line commonly connected to second terminals of all of the plurality of second conductive lines.

12. The image sensing device according to claim 11, wherein the bottom switching circuit includes:
a first bottom switching element, a first terminal of the first bottom switching element being connected to the first bottom common line, a second terminal of the first bottom switching element being connected to the first bottom test pad; and
a second bottom switching element, a first terminal of the second bottom switching element being connected to the second bottom common line, a second terminal of the second bottom switching element being connected to the second bottom test pad.

13. The image sensing device according to claim 1, wherein:
the plurality of first conductive lines and the plurality of second conductive lines include conductive lines disposed to vertically overlap a pixel array that includes unit pixels that are arranged in the pixel array.

14. The image sensing device according to claim 13, wherein:
the plurality of first conductive lines and the plurality of second conductive lines extend parallel to each other in the first direction within a same metal layer.

15. The image sensing device according to claim 1, wherein the plurality of first conductive lines includes:
signal output lines formed to transfer pixel signals generated by photoelectric conversion of incident light by unit pixels.

16. The image sensing device according to claim 1, wherein the plurality of second conductive lines includes:
power transmission lines formed to supply a power-supply voltage.

17. An image sensing device comprising:
a plurality of first conductive lines configured to extend parallel to each other in a first direction;
a plurality of second conductive lines located adjacent to the first conductive lines and configured to extend parallel to each other in the first direction;
a top test pad circuit configured to include a first top test pad and a second top test pad;
a bottom test pad circuit configured to include a first bottom test pad and a second bottom test pad;
a plurality of first top switching elements, first source or drain terminals of the plurality of first top switching elements being connected in a one-to-one correspondence with first terminals of the first conductive lines, second source or drain terminals of the plurality of first top switching elements being commonly connected to the first top test pad;
a plurality of second top switching elements, first source or drain terminals of the plurality of second top switching elements being connected in a one-to-one correspondence with first terminals of the second conductive lines, second source or drain terminals of the plurality of second top switching elements being commonly connected to the second top test pad;
a plurality of first bottom switching elements, first source or drain terminals of the plurality of first bottom switching elements being connected in a one-to-one correspondence with second terminals of the first conductive lines, second source or drain terminals of the plurality of first bottom switching elements being commonly connected to the first bottom test pad; and
a plurality of second bottom switching elements, first source or drain terminals of the plurality of second bottom switching elements being connected in a one-to-one correspondence with second terminals of the second conductive lines, second source or drain terminals of the plurality of second bottom switching elements being commonly connected to the second bottom test pad.

18. The image sensing device according to claim 17, wherein the plurality of first conductive lines includes:
signal output lines formed to transfer pixel signals generated by photoelectric conversion of incident light by unit pixels.

19. The image sensing device according to claim 17, wherein the plurality of second conductive lines includes:
power transmission lines formed to supply a power-supply voltage.
